(19) United States
(12) Patent Application Publication
(10) Pub. No.: US 2007/0080446 A1
(43) Pub. Date: Apr. 12, 2007

(54) Protective enclosure for handheld electronic device

(75) Inventor: Michael A. Maloney, Caledon (CA)

Correspondence Address: BERESKIN AND PARR, 40 KING STREET WEST, BOX 401, TORONTO, ON, M5H 3Y2, CA

(73) Assignee: Maxita International Corp., Caledon (CA)

(21) Appl. No.: 11/299,776

(22) Filed: Dec. 13, 2005

Related U.S. Application Data
(60) Provisional application No. 60/724,288, filed on Oct. 7, 2005.

(51) Int. Cl. H01L 23/12

(52) U.S. Cl. 257/704

(57) ABSTRACT

A protective enclosure for use with a handheld electronic device having a casing with controls. The protective enclosure includes an inner skin shaped to receive and form fit a major portion of the casing of the electronic device, and an outer skin shaped to receive and form fit the inner skin, having openings located to allow access to the selected controls. The inner skin and the outer skin are made from an elastomeric material, preferably silicone. Together, the skins protect the electronic device from impacts, dust, debris, perspiration or other external factors, while permitting normal function of the controls of the electronic device. The inner skin may include control portions that register with at least some of the selected controls having tactile surfaces that facilitate the operation of the controls.

### CROSS REFERENCE TO RELATED APPLICATION

This is a non-provisional application claiming priority of provisional application Ser. No. 60/724,288 filed on Oct. 7, 2005, which is incorporated herein by reference.

### FIELD OF THE INVENTION

The invention relates generally to protective enclosures for electronic devices and more particularly to elastomeric protective enclosures for handheld electronic devices such as portable audio devices.

### BACKGROUND OF THE INVENTION

Handheld electronic devices such as personal audio devices and cellular phones are becoming increasingly popular. These electronic devices typically comprise a hard plastic casing having openings for controls that allow users to interact with the device. While this type of casing provides a measure of protection for the internal electronic components, the devices remain susceptible to damage caused by liquid, dust and other debris entering through small cracks between the controls and the casing, and by users dropping or otherwise subjecting the devices to impacts. Accordingly, there exists a need to provide additional protection for handheld electronic devices.

There exist various types of protective covers for personal audio devices and other handheld electronic devices, including leather or rubberized covers that enclose the entire device and provide protection against impacts. However these types of enclosures only protect the device when it is not in use. In order to use the device, the device must be removed from the cover where it becomes susceptible to impact damage. These prior art protective covers also tend to be bulky and unsightly, or otherwise plain, boring and unappealing.

There also exist protective covers known as skins shaped to form fit personal audio devices, which have openings or cutouts that provide access to the input keys and output elements such as screen displays. These skins are made of an elastomeric material that provides impact protection. They also tend to be more aesthetically pleasing than older types of covers. However, these skins do not cover the controls of the device. There remain small openings between the controls and the casing where dust, liquid and debris may enter the casing and damage the internal electronics of the device.

Accordingly, there is a need for a stylish, customizable and functional protective enclosure for handheld electronic devices that protects the device against impacts while sealing the internal circuitry from foreign matter.

### SUMMARY OF THE INVENTION

The present invention is directed to a protective enclosure for a handheld electronic device having a casing with controls, comprising an inner skin shaped to form fit at least a major portion of the casing of the electronic device and to cover selected controls, and an outer skin shaped to receive and form fit the inner skin, having openings located to allow access to the selected controls. The inner skin is made from a first elastomeric material selected to allow a user to interact with the selected controls, and the outer skin is made from a second elastomeric material selected to provide impact protection.

The inner skin has control portions that register with at least some of the selected controls of the electronic device, the control portions having a first thickness selected to allow for user manipulation of the controls. The openings of the outer skin comprise cut-outs that register with the control portions of the inner skin.

The inner skin and the outer skin are preferably made of silicone. The inner skin material is preferably transparent or translucent.

### BRIEF DESCRIPTION OF THE DRAWINGS

The invention will now be described, by way of example only, with reference to the following drawings, in which:

FIG. 1 is an exploded front perspective view of a protective enclosure made in accordance with a preferred embodiment of the subject invention, shown in conjunction with a personal handheld electronic device;

FIG. 2 is an exploded rear perspective view of the protective enclosure and personal electronic device shown in FIG. 1;

FIG. 3 is a front perspective view of the inner skin of the subject protective enclosure, shown installed on a personal electronic device;

FIG. 4 is a cross-sectional view of the inner skin of the subject protective enclosure;

FIG. 5 is a cross-sectional view of the outer skin of the subject protective enclosure;

FIG. 6 is a front view of the subject protective enclosure shown installed on a personal electronic device;

FIG. 7 is a cross-sectional view of the subject protective enclosure installed on a personal electronic device, taken along the line 7-7 in FIG. 6;

FIG. 8 is a cross-sectional view of the subject protective enclosure installed on a personal electronic device, taken along line 8-8 in FIG. 7;

FIG. 9 is a front perspective view of the subject protective enclosure installed on a personal electronic device, showing a lanyard connected thereto; and

FIG. 10 is a rear perspective view of the subject protective enclosure installed on a personal electronic device.

### DETAILED DESCRIPTION OF THE INVENTION

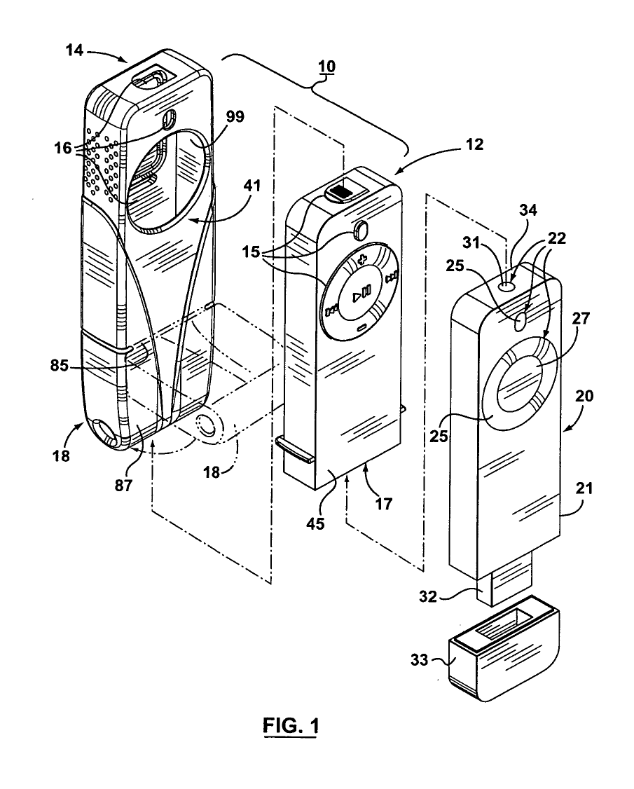

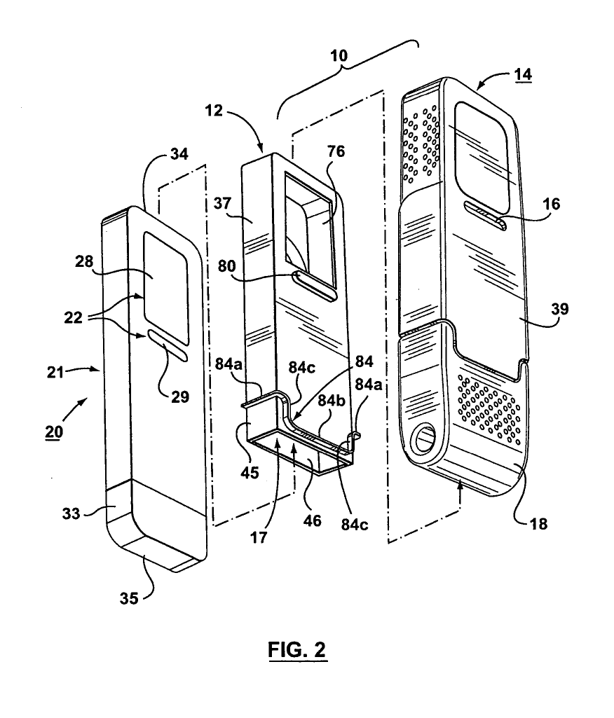

Referring to FIGS. 1 and 2, illustrated therein is a protective enclosure 10 made in accordance with the present invention, shaped to enclose handheld electronic device 20. Handheld electronic device 20 comprises a casing 21 that houses the internal electronic components of the device, and a plurality of input/output controls 22 that enable a user to interact with the device. Controls 22 may comprise input/output (I/O) devices such as a navigation control 25, LED indicator 26, play control 27, power slide switch 28, battery test button 29, audio plug 31 and a data connector 32 covered by data connector cap 33. Casing 21 is typically a hard plastic shell that encloses the internal electronics of the personal audio device 20 and provides some protection for the internal electronics from the external environment.

Protective enclosure 10 is a two layer protective enclosure comprising an inner skin 12 and an outer skin 14. Inner skin 12 is shaped to receive and form fit a major portion of casing 21 of electronic device 20 and to cover selected controls 22. Inner skin 12 is made from an elastomeric material such as silicone that enables a user to interact with selected controls 22. Outer skin 14 is shaped to fit over inner skin 12 when electronic device 20 is inserted in inner skin 12. Outer skin 14 is made from an elastomeric material that provides impact protection. Outer skin 14 has openings 16 that are located so as to allow access to selected controls 22. Protective enclosure 10 is typically sold as an aftermarket accessory for electronic device 20, although enclosure 10 could be made by an OEM (original equipment manufacturer) and sold together with handheld electronic device 20.

Inner skin 12 is preferably a thin, pliable membrane in the form of a sheath having a bottom opening 17 for receiving handheld electronic device 20. Inner skin 12 comprises control portions 15 that register with and overlay selected controls 22. Control portions 15 may comprise various embossed, raised, textured or otherwise contoured areas shaped to facilitate manipulation of selected controls 22. When inner skin 12 is deployed on electronic device 20, a form fit is achieved between the inner skin 12 and at least a major portion of casing 21 and controls 22. The form fit creates a partial seal around most of electronic device 20 and provides a user with the opportunity to maintain tactile interaction with selected controls 22 by manipulating control portions 15.

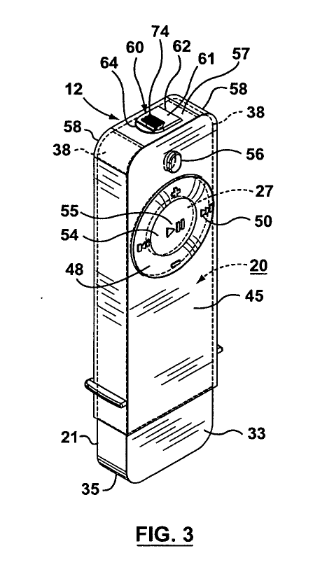

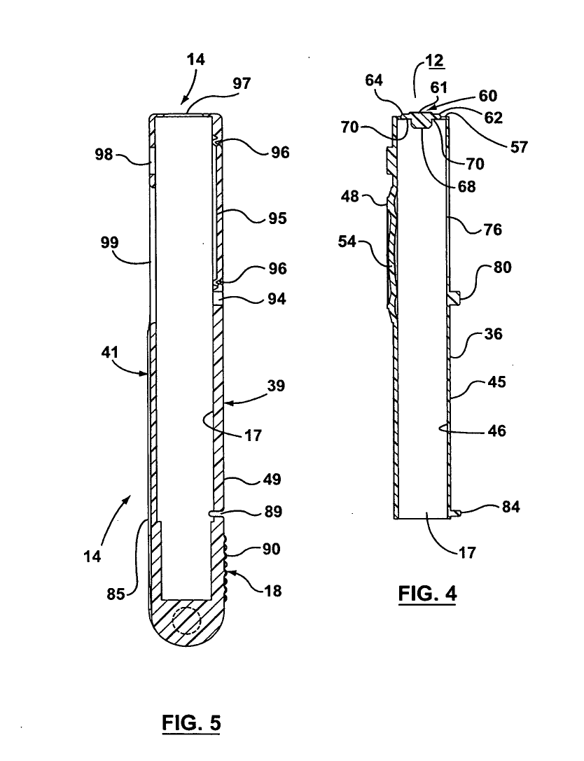

As best shown in FIG. 4, inner skin 12 has an exterior surface 45 and an interior surface 46 defining a cavity shaped to receive and cover most of casing 21 of electronic device 20. As shown in FIG. 3, inner skin 12 covers casing 21 from its top end 34 to a point near bottom end 35, so as to leave data connector cap 33 exposed. Interior surface 46 has interior dimensions providing a form fit with casing 21 that allows users to actuate controls 22 by manipulating exterior surface 45. When hand pressure is applied to exterior surface 45 in control portions 15, the pressure is elastically transmitted through the thickness of inner skin 12 to interior surface 46 where the pressure is further transmitted to the desired controls 22. For example, depressing the exterior surface 45 may cause the interior surface 46 to protrude inward and further depress a push button, such as play control 27. Alternatively, a shearing motion may be transmitted from the exterior surface 45 to the interior surface 46 where contact friction transmits the shear force to a slidable switch, such as power switch 28. To allow transmission of these forces, control portions 15 of inner skin 12 should have relatively thin walls between the exterior surfaces 45 and interior surface 46. In the particular embodiment, the thickness of inner skin 12 is in the range of 0.25 mm-0.75 mm, when inner skin 12 is made from silicone. The thickness of inner skin 12 is preferably about 20-70% of the thickness of outer skin 14.

The interior surface 46 of inner skin 12 preferably has dimensions slightly smaller than casing 21. In this manner, inner skin 12 stretches over casing 21 and conforms to the shape of casing 21 as well as any protruding controls 22. In addition, any of controls 22 that are slightly recessed within casing 21 may be directly contacted by interior surface 46 due to the tight elastic fit. However, inner skin 12 should not fit too tight around casing 21, otherwise some of protruding controls 22 may be locked in an actuated state. In the specific example described herein, the dimensions of interior surface 46 are 0.1 mm smaller than the cross-wise dimensions of casing 21. In general, skins 12, 14 should be about 0.02 mm to 0.25 mm smaller than outer dimensions of the surface to be covered, although, this can vary, depending upon the elasticity of a given material.

Interior surface 46 is preferably shaped to form a partial liquid impermeable seal with casing 21 near opening 17. In general, the seal is formed anywhere between bottom end 35 and lowermost control 22 such that any gaps between controls 22 and casing 21 are sealed from the external environment. In practice, the seal provides a liquid resistant barrier that protects the internal circuitry from damage by liquid or debris that would normally enter the personal audio device through spaces around the controls. Similar seals may be employed around other openings in inner skin 12 or outer skin 14.

Outer skin 14 is preferably a thin, pliable membrane in the form of a sheath having a bottom flap portion 18 that opens to receive inner skin 12, and openings 16 located to register with control portions 15 of inner skin 12. As best shown in FIG. 5, outer skin 14 has an internal surface 47 shaped to conform to exterior surface 45 of inner skin 12 and an external surface 49. Outer skin 14 is preferably shaped to cover inner skin 12 and any portion of electronic device 20 not covered by inner skin 12. However, it should be understood that outer skin 14 need not cover all portions of electronic device, and that outer skin 14 could include cut-outs for selected controls that are not covered by inner skin 12.

The thickness of outer skin 14 is selected to permit absorption of shocks that are incident on external surface 49. Outer skin 14 is preferably thicker than inner skin 12, and is preferably about 1.5 mm. In combination, the overlapping skins 12, 14 provide a combined wall thickness that significantly reduces the amount of damage to electronic device 20. As a practical consideration, outer skin 14 should be thick enough to prevent damage that would occur in normal operation, such as damage from dropping, banging or scraping device 20.

In general, external surface 49 of outer skin 14 can be any desirable aesthetic or functional shape, so long as it does not significantly hinder the normal operation of controls 22.

Inner skin 12 and outer skin 14 are formed from an elastomeric material that has a shape memory so that any deformations will be non-permanent. The material may be either a thermoset or thermoplastic and is typically a rubber-like compound such as silicone. The preferred composition for the inner and outer skins 12, 14 is either a platinum cured silicone or a peroxide cured silicone.

An elastomeric material such as silicone provides a responsive surface finish having a soft, yet tacky feel, which provides for easy gripping of the device and proper actuation of the controls. In addition, the surface finish helps to frictionally form seals around the device. Other surface finishes may be utilized which may improve the feel or function of the device. Such surfaces may include a smoother, low-friction, surface on a portion of protective enclosure 10 that permits easier application and removal of the skins 12, 14.

Inner skin 12 is preferably fabricated from a translucent or transparent silicone material that allows for visual operation of controls 22 However, some portions of inner skin 12 could be opaque, as long as those control portions 15 that overlay controls 22 requiring visibility for operation are transparent or translucent. Outer skin 14 may be fabricated from any combination of transparent, translucent or opaque compounds in any location. Both inner skin 12 and outer skin 14 may be coloured to improve aesthetics or functionality.

Protective enclosure 10 of the present invention may be shaped to fit various different types of electronic devices, including personal audio devices, cell phones, and portable computer. In the embodiment of the invention shown in the figures, protective enclosure 10 is shaped to fit the casing and controls of an ipod Shuffle (trademark) MP3 player manufactured by Apple Computer. In the description that follows, this embodiment will be described in detail, with respect to the casing and controls that are specific to this type of MP3 player. However, it should be apparent to one skilled in the art that the subject protective enclosure could be adapted to fit other types of handheld electronic devices.

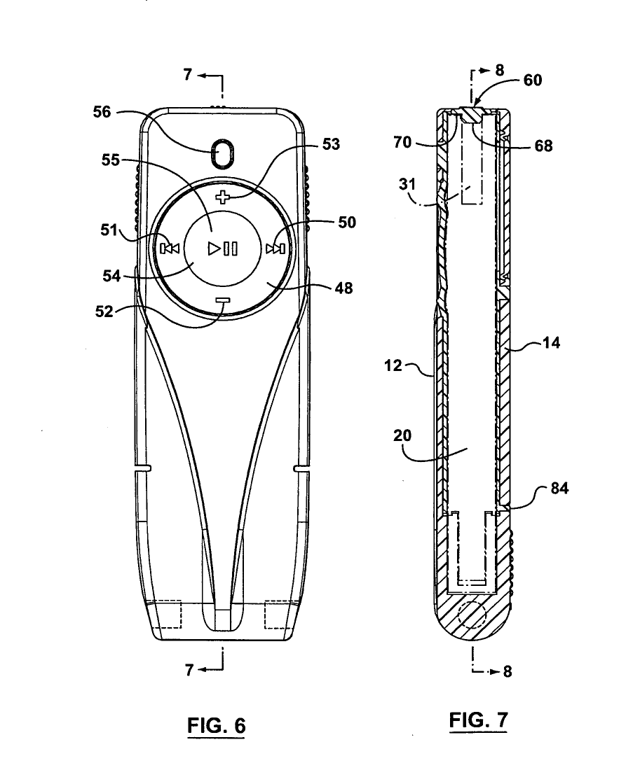

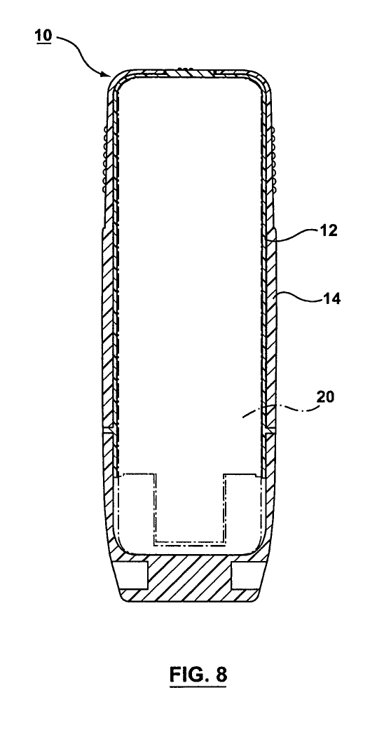

Referring now primarily to FIGS. 3, 4 and 6, inner skin 12 comprises variety of control portions 15 that overlay the controls of an iPod Shuffle MP3 player, including a toroidal ridge 48 that wraps over the semi-toroidal navigation control 25. On the peak of the toroidal ridge 48 are four embossments, forward 50, reverse 51, minus 52 and plus 53, located on the right, left, lower and upper portions of exterior surface 45 respectively, to correspond to the respective controls they actuate on navigation control 25. These embossments provide tactile feedback so that a user may manipulate navigation control 25 through ridge 48 without visually managing personal audio device 21. Radially within toroidal ridge 48 is a convex contour 54 for interfacing with convex play control 27, having a “play/pause” embossment 55 formed on the peak of convex contour 54.

Located above toroidal ridge 48 is a longitudinally extending oblong embossment 56 for viewing lights of LED indicator 26 through inner skin 12. It is noted that at least this area of inner skin 12 should be translucent or transparent for viewing LED indicator 26. However, in other areas where it is not advantageous to see through inner skin 12, opaque materials may be utilized.

The top end 57 of inner skin 12 has rounded corners 58 that conform to filleted edges 38 of casing 21, so as to maintain the general shape and appearance of electronic device 20 when enclosure 10 is deployed thereon, and provide a snug fit over casing 21.

As best shown in FIGS. 3 and 4, inner skin 12 includes an audio plug cover 60 on top end 57 of inner skin 12. Audio plug cover 60 comprises a generally rectangular, relatively thick hinged flap 61, which is attached to top end 57 by hinged base 62. Flap 61 has arcuate free end 64 which is free to pivot up or down relative to the hinged base 62. Depending from a central portion of flap 61 is a cylindrical plug 68 that projects inward to engage audio plug 31. Surrounding cylindrical plug 68 is a sealing flange 70 provides a seal around audio plug 31 when audio plug cover 60 is closed. Optionally, the top portion of flap 61 may have ribs 74 that assist with griping and opening audio plug cover 60.

As best shown in FIGS. 2 and 4, back face 36 of inner skin 12 has a generally rectangular switch opening 76 to provide access to power switch 28. Inner skin 12 should be sufficiently taut around switch opening 76 to form a partial seal around the power switch 28. Sealing reduces the possibility of foreign matter entering other portions of the device and causing damage. Located just below switch opening 76 is a horizontal oblong embossment 80 that overlays battery test button 29. When horizontal oblong embossment 80 is depressed, it protrudes into and actuates battery test button 29.

Inner skin 12 also comprises a separation ridge 84 that runs continuously along back face 36 and sides 37 of exterior surface 45. Separation ridge includes side portions 84a located along the sides of inner skin 12, back portion 84b located on back portion of inner skin 12, and two spline sections 84c that connect each of the two side portions 84a to the back portion 84b in an “s” shaped manner. The particular shape of separation ridge 84 allows the outer skin 14 to fold out and uncover USB connector 32 when outer skin 14 is installed on inner skin 12.

Referring now primarily to FIGS. 5, 9 and 10, outer skin 14 comprises a variety of openings 16 located to register with the specific controls 22 of the ipod Shuffle MP3 player. Outer skin 14 also includes a number of functional features adapted especially for the iPod Shuffle, including lower flap 18 located on the bottom end of outer skin 14 to protect USB connector 32 and to house data connector cap 33. Lower flap 18 is shaped to ensure proper sealing and containment of USB connector 32 when lower flap 18 is closed. Lower flap 18 includes an elastic hinge portion 85 extending along a transverse line in the front face of outer skin, a back face portion 87 and sidewalls 88. Back face 87 and sidewalls 88 are separated from the back face 39 of outer skin 14 by a gap 89. When outer skin 14 encloses inner skin 12, and the lower flap 18 is closed, gap 89 is filled by the separation ridge 84 of inner skin 12. To access USB connector 32, lower flap 18 is initially stretched downward to widen gap 89. The lower flap 18 is then folded forward about elastic hinge portion 85, usually 900 from the closed position, as shown in ghost lines in FIG. 1. Back face 87 of lower flap 18 may have a series of bumps 90 that assist with gripping lower flap 18 while attaching and detaching data connector cap 33.

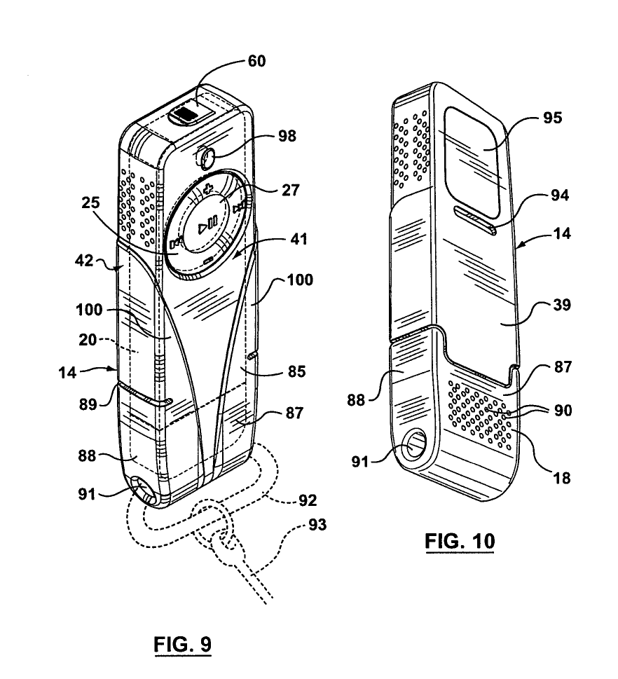

As shown in FIG. 9, sidewalls 88 of lower flap 18 may comprise a pair of indentations 91 shaped to allow attachment of a lanyard connector 92, so that a lanyard 93 can be connected to protective enclosure 10.

Referring now to FIGS. 5 and 10, located near the center of back face 39 of outer skin 14 is a horizontal oblong aperture 94 that provides access to battery test button 29 via horizontal oblong embossment 80 on inner skin 12. The open dimensions of horizontal oblong aperture 94 are generally slightly larger than the outside dimensions of embossment 80 so as to reduce frictional interference when depressing embossment 80 to actuate battery test button 29.

Back face 39 of outer skin 14 includes a thin rectangular canopy 95 shaped for actuation of power switch 28. As shown in FIG. 5, canopy 95 includes a pair of opposing serpentine grooves 96 that create a spring-like structure around the edges of canopy 95, which provide greater flexibility in the area around power switch 28 so that the power switch 28 can be easily slid between each state. Additionally, serpentine grooves suspend canopy 95 above power switch 28 to create an open cavity between canopy 95 and power switch 28. Functionally, when canopy 95 is elastically depressed, it contacts power switch 28 thus applying a normal force, which may then induce transverse frictional forces. The spring structure provided by grooves 96 allows canopy 95 to be pulled up or down, thus sliding power switch 28 between different positions.

Referring again to FIGS. 5 and 9, front face 41 of outer skin 14 includes a longitudinally extending oblong aperture 98 that allows viewing of LED indicator 26 through vertical oblong embossment 56 of inner skin 12. Below vertical oblong aperture 98 is a circular opening 99 for accessing navigation control 25 and play control 27 via inner skin 12. On the top end of outer skin 14 is an audio plug aperture 97 that registers with audio plug 60.

Outer skin 14 may also include aesthetic features such as a curvilinear embosses 100 that sweep downward along front face 41 and side walls 42 of outer skin 14. If the outer skin 14 is translucent, the thicker curvilinear embosses 100 will appear darker than other portions of outer skin 14. Additionally, if inner skin 12 is a different colour than outer skin 14, then the lower portion of protective enclosure 10 will be accented.

Manufacturing of inner skin 12 and outer skin 14 is typically completed using two separate injection molding processes. Injection molding of protective enclosure 10 provides for components with low cost, high production rates and good tolerances. However, it is feasible to use other manufacturing processes known in the art, for example, compression molding, blow molding, thermoforming and other manufacturing methods suitable for the materials and shapes be processed.

In use, inner skin 12 and outer skin 14 are typically sold together in matched pairs, with inner skin 12 already inserted into outer skin 14. A user would typically deploy protective enclosure 10 onto electronic device 20 by flipping up flap 18, removing USB cap 33, and then slowly inserting electronic device 20 into inner skin 12 when inner skin 12 is covered by outer skin 14. However, protective enclosure 10 could be deployed on electronic device 20 by first installing inner skin 12 on electronic device 20 and then inserting the skinned device 20 into outer skin 14.

Since the inner skin 12 and outer skin 14 are removable from each other, different inner and outer skins could be paired with each other. This interchangeability allows a user to customize the appearance of a personal electronic device.

Although the preferred embodiment of the subject protective enclosure 10 comprises various functional features as described hereinabove, it should be appreciated that protective enclosure 10 could include various other types of other openings and features. For instance, protective enclosure 10 could include openings for LCD screens, data connection ports or even camera. Optionally, outer skin 14 may include-gripping surfaces such as side dimples on the external sidewalls.

Optionally, protective enclosure 10 may comprise additional skin layers (not shown) that overlay portions of outer skin 14 to increase shock protection, provide alternate aesthetic designs or add other features.

Although the inner and outer skin have been described as providing specific benefits, many other benefits may be realized using a multi-layer protective enclosure. Some of these benefits include shock protection, scratch resistance, tactile feedback, customization, aesthetics and sealing. Any single benefit or combination of benefits achieved using a multi-layer protective enclosure as described would not detract from the scope of the present invention.

It should therefore be apparent to one skilled in the art that various modifications can be made to the embodiment disclosed herein, without departing from the present invention, the scope of which is defined in the appended claims.

1. A protective enclosure for a handheld electronic device having a casing with controls, comprising:
a) an inner skin shaped to receive and form fit at least a major portion of the casing of the electronic device and to cover selected controls, the inner skin being made from a first elastomeric material selected to allow a user to interact with the selected controls; and
b) an outer skin shaped to receive and form fit the inner skin, the outer skin having openings located to allow access to the selected controls, the outer skin being made from a second elastomeric material selected to provide impact protection.

2. The enclosure defined in claim 1, wherein the inner skin comprises control portions that register with the selected controls of the electronic device, the control portions having a first thickness selected to allow for user manipulation of at least some of the selected controls.

3. The enclosure defined in claim 2, wherein some of the control portions of the inner skin comprise contoured areas shaped to facilitate user manipulation of at least some of the selected controls.

4. The enclosure defined in claim 3, wherein the contoured areas comprise embossed areas shaped to register with selected portions of the controls.

5. The enclosure defined in claim 2, wherein the openings of the outer skin comprise cutouts that register with the control portions of the inner skin.

6. The enclosure defined in claim 1, wherein the inner skin comprises a first sheath having a first opening shaped to receive the electronic device.

7. The enclosure defined in claim 6, wherein the outer skin comprises a second sheath having a second opening shaped to receive the inner sheath when the electronic device is inserted therein.

8. The enclosure defined in claim 6, wherein the inner skin is shaped to provide a liquid resistant seal around the casing at a location adjacent to the first opening.

9. The enclosure defined in claim 1, wherein the inner skin and the outer skin are shaped so that all of the controls of the electronic device are covered by either the inner skin or the outer skin.

10. The enclosure defined in claim 1, wherein the first elastomeric material is selected to provide for visibility of at least some of the selected controls.

11. The enclosure defined in claim 10, wherein the first elastomeric material is transparent.

12. The enclosure defined in claim 10, wherein the first elastomeric material is translucent.

13. The enclosure defined in claim 2, wherein the first thickness is in the range of 0.25 millimeters to 0.75 millimeters.

14. The enclosure defined in claim 1, wherein the outer skin has a second thickness, the second thickness being greater than the first thickness.

15. The enclosure defined in claim 14, wherein the first thickness is 20-70 percent of the second thickness.

16. The enclosure defined in claim 14, wherein the second thickness is approximately 1.5 millimeters.

17. The enclosure defined in claim 1, wherein the first elastomeric material is silicone.

18. The enclosure defined in claim 1, wherein the second elastomeric material is silicone.

19. The enclosure defined in claim 7, wherein the outer skin comprises a flap portion for covering the second opening, the flap portion being pivotal between a closed position covering the second opening and an open position allowing the electronic device to be inserted into the outer skin through the second opening.

20. The protective enclosure of claim 1, wherein the outer skin has a textured outer surface.
